(19) United States
(12) Patent Application Publication
(10) Pub. No.: US 2014/0325129 A1
(43) Pub. Date: Oct. 30, 2014

(54) METHOD AND APPARATUS FOR ACTIVE RANGE MAPPING FOR A NONVOLATILE MEMORY DEVICE

(71) Applicant: MICRON TECHNOLOGY, INC., Boise, ID (US)

(72) Inventor: Brent Ahlquist, Loomis, CA (US)

(21) Appl. No.: 14/327,267

(22) Filed: Jul. 9, 2014

Related U.S. Application Data
(63) Continuation of application No. 12/347,983, filed on Dec. 31, 2008.

(51) Int. Cl. G11C 14/00; G11C 15/04; G06F 12/02

(52) U.S. Cl. CPC G11C 14/0018; G06F 12/0246; G11C 14/0009; G11C 15/046; G06F 2212/7208
USPC 711/103

(57) ABSTRACT

Methods and systems are provided that may include a nonvolatile memory to implement a virtual random access memory space.

### CROSS-REFERENCE TO RELATED APPLICATION

This application is a continuation application of U.S. application Ser. No. 12/347,983, filed Dec. 31, 2008, titled “METHOD AND APPARATUS FOR ACTIVE RANGE MAPPING FOR A NONVOLATILE MEMORY DEVICE,” the disclosure of which is incorporated by reference herein.

### BACKGROUND

1. Field

The subject matter disclosed herein relates to a method and apparatus for active range mapping for a nonvolatile memory device.

2. Information

Nonvolatile memory devices, such as Phase-Change Memory (“PCM”), flash memory, or Electrically Erasable Programmable Read-Only Memory (“EEPROM”) are sometimes packaged within an electrical system. For example, such nonvolatile memory devices may be sold within a computer system or a digital camera, for example. Such nonvolatile memory devices sometimes use a specific nonvolatile memory device interface, such as a Low Power Double Data Date bus for a Nonvolatile Memory (LPDDR-NVM). However, use of such an interface may require use of certain specific instructions when transmitting data or other information via a bus to a nonvolatile memory device. For example, in the event that a bus is adapted to be used with a Dynamic Random Access Memory (DRAM) protocol, a special instruction may be utilized in order to change a page size when accessing a memory space within a nonvolatile memory.

In some systems, a nonvolatile memory device utilizes a smaller page size than does a DRAM. Accordingly, in order to activate a page requiring the communication of more page address bits in such systems, an additional instruction therefore may have to be sent across a bus to a nonvolatile memory. Such an additional instruction may complicate a nonvolatile memory device.

### BRIEF DESCRIPTION OF DRAWINGS

Non-limiting and non-exhaustive aspects are described with reference to the following figures, wherein like reference numerals refer to like parts throughout the various figures unless otherwise specified.

FIG. 1 is a schematic diagram of a device according to one implementation.

FIG. 2 is a schematic diagram of an electronic device according to one implementation.

FIG. 3 is a flow diagram of a process for performing write operations to a nonvolatile memory according to one implementation.

FIG. 4 illustrates an abstraction of elements within a nonvolatile memory according to one implementation.

FIG. 5 illustrates a flow chart of a range mapping operation according to an implementation.

FIG. 6 illustrates a method for accessing a memory address stored in a nonvolatile memory according to one implementation.

### DETAILED DESCRIPTION

In the following detailed description, numerous specific details are set forth to provide a thorough understanding of claimed subject matter. However, it will be understood by those skilled in the art that claimed subject matter may be practiced without these specific details. In other instances, well-known methods, procedures, components and/or circuits have not been described in detail so as not to obscure claimed subject matter.

Some exemplary methods and systems are described herein that may be used to allow a nonvolatile memory device to be utilized with a Random Access Memory (RAM) interface, such as a Dynamic RAM (DRAM) interface. Such a nonvolatile memory may comprise, for example, Phase-Change Memory (“PCM”), flash memory, or Electrically Erasable Programmable Read-Only Memory (“EEPROM”). As discussed herein, one implementation may-utilize a standard DRAM interface as a portal to a non-volatile memory without requiring modification of a standard DRAM interface.

A DRAM may utilize a memory space comprised of pages. A DRAM may utilize pages that have a different size than a fundamental access unit utilized in a nonvolatile memory device. A DRAM may include memory locations arranged in rows and columns in an array. A row may comprise, for example, 1024 memory locations, each capable of storing one byte (i.e., a total of 1 Kbyte of storage). A DRAM may also include a number of columns. In a DRAM, each row may comprise a page. In one implementation, a page may be activated and then all of the information or data stored in the page may be transferred to a memory buffer with the DRAM. Information for a particular column may be retrieved after a page has been transferred to a buffer. In accessing a particular memory location, a processor may activate a Row Access Strobe (RAS) cycle to specify a row to be activated (e.g., high bits), and may active a Column Access Strobe (CAS) cycle to specify a column (e.g., low bits) where a memory location is to be found.

Some computing systems utilize nonvolatile memory devices. Such nonvolatile memory devices may be accessed and information may be written to or retrieved from such nonvolatile memory devices based on execution of certain nonvolatile memory device-specific commands. One or more overlay windows may be utilized as a command portal to manage and access capabilities of a nonvolatile memory device, where such command portal exists within a memory space accessed using a DRAM protocol. In other words, “Active Range Mapping,” or use of such a command portal behind a standard interface, such as DRAM may be provided.

A size of a physical memory page in a memory core may be larger (or smaller) than a page size used by a DRAM interface. Accordingly, in order to access data at a particular memory location, some standard DRAM protocols have been altered to require use of two commands to provide the row addresses necessary for RAS cycles, as opposed to a single CAS cycle as would be used according to a standard DRAM protocol. Moreover, a DRAM bus, such as an LPDDR bus, may not have or define an existing instruction to allow two RAS cycles in this manner and it may be necessary to petition a standards body governing an LPDDR bus to allow this capability.

In one particular implementation, as discussed below, a nonvolatile memory may be utilized with a RAM bus, such as an LPDDR bus, while using a single standard RAS cycle. It should be understood, however, that other types of buses adapted for communication with a DRAM device may be used. Such a nonvolatile memory may organize memory in such a way that it presents a “RAM memory space” as an abstraction that appears to mimic a DRAM or other type of RAM. Such a nonvolatile memory may therefore be utilized in conjunction with a DRAM bus.

As discussed below, an underlying physical device memory, for instance, a nonvolatile memory, may be presented through a standard RAM memory interface having dimensions according to the DRAM interface utilized. “MAP RAM,” or “virtual RAM,” as used herein, may refer to an externally presented physical address space used to access mapped ranges of underlying physical memory. Although not limited to nonvolatile physical memory, the underlying memory is referred to herein as “NWM.” Onward Ranges of NVM memory may be accessed like DRAM after a MAP RAM page has been opened via a DRAM interface. MAP RAM pages may have protections/attributes associated with the NVM ranges to which they are mapped such as, for example, those that are essentially used to filter access to the NVM ranges. MAP RAM, as used herein, may also refer to a virtual memory space implemented by which memory types such as, for example, an EEPROM, flash, or PCM are accessed. An NVM range may span one or more MAP RAM pages, where a standard DRAM page size is, for instance, 1 Kbytes. Each page in an NVM Range may correspond to one or more pages in NVM (e.g.., core memory). Such a device may include a range mapping table that maps an NVM range of pages with one or more pages of physical memory. In one implementation, each accessible unit or page of physical memory may contain, for example, 64 Bytes. Accordingly, a 1 Kbyte page in MAP RAM may correspond to 16 64 Byte pages in physical memory (i.e., because 16 64 Byte pages contain a total of 1024 Bytes (1 Kbyte)).

Upon receiving an access request to open a particular page of a MAP RAM, a nonvolatile memory device may refer to a range mapping table entry which maps a page in MAP RAM with one or more pages in a physical memory. A range mapping table may also refer to an attributes register which may provide attributes for various MAP RAM pages and associated with physical memory. Such attributes may indicate whether a page is read-only, write-only, or inaccessible, to name just a few examples among many. Such attributes may therefore be used for security purposes to prevent certain memory locations from being accessed or written to. A range mapping table may, upon an MAP RAM page opening, transmit a message to one or more active page registers indicating specific associated physical memory pages to map and attributes to assign for the opened MAP RAM page.

Internal control logic of a memory device may check a Range Mapping Table comparing a physical MAP RAM page accessed with NVM Ranges entries stored in the Range Mapping Table. There should be a match somewhere, or else MAP RAM has no association. There could also be a default read or write overlay window. When a MAP RAM page lies within a Range Mapping Table entry, an associated physical memory range and its attributes are transferred to an Active page register that is associated with that particular MAP RAM access. An active page register and an associated page buffer may be utilized by the device to hold a Range Mapping Table entry and NVM Range page data accessed upon MAP RAM page opening. The device may write such data/information to an associated active page register and page buffer where it may be subsequently reside until it is processed, e.g., read or modified according to DRAM protocols. For example, such data may be transmitted out of a memory device to a processor or other system component for subsequent processing/usage.

In one implementation, a nonvolatile memory device may require the use of overlay window(s) to implement indirect write operations to physical memory via a memory buffer and device command and status interface.

Overlay windows in a nonvolatile memory device may be default associations within a Range Mapping Table. For example, at reset of a memory device, an entire Range Mapping Table may be initialized with entries that are stored somewhere in non-volatile memory. Such entries may have been configured in a factory or through some command in the field. Unless specifically indicated otherwise, at reset Range Mapping Table entry attributes may indicate that an associated NVM range will correspond to either an overlay window type or a specific NVM range mapping. The type of overlay window accessed would depend on the host issuing a read or write operation. Only after a specific command is received in a write overlay window to transition Range Mapping Table associations to their runtime attributes value would a default write overlay window remap to its true MAP RAM and NVM Range associations, for example. Read protections, of course, may require an overlay window default to always be set at reset. If a particular MAP RAM page does not match a Range Mapping Table entry, it may always default to a read and write overlay window.

According to one implementation, as discussed herein, a separate overlay window may be utilized for a write operation versus an overlay window for a read operation. One implementation, as discussed herein, may provide a method and system for reading from and writing to a nonvolatile memory device without having to utilize any DRAM, standard-specific messaging commands. For example, in at least one implementation, a protocol-specific command may have to be provided to a nonvolatile memory device in order to cause the nonvolatile memory device to open an overlay window. In such an implementation, read operations and write operations may be performed within the same overlay window. Accordingly, in the event that information stored in a command register is to be read, an entire overlay window may be opened. Moreover, if information is to be written to a memory buffer, the same overlay window would need to be opened.

According to one particular implementation, a nonvolatile memory device may include at least one write overlay window. Such a nonvolatile memory device may also include at least one read overlay window. Such write and read overlay windows may overlap, but may, however, be treated as separate portals. In other words, at least one write overlay window does not share any registers or space in memory with at least one read overlay window. Accordingly, at least one write overlay window may therefore be logically separate from at least one read overlay window. If a nonvolatile memory device does not support direct write operations, one or more write overlay windows may remain permanently opened in such a nonvolatile memory device. In the event that a write command is received by a nonvolatile memory device, information for such a write command may be written to one or more write overlay windows without a nonvolatile memory device having to first explicitly open a write overlay window.

If a nonvolatile memory supports direct write operations, a nonvolatile memory-specific command may close an underlying write overlay window prior to such a direct write capability being made available. A device may start with all write overlay windows initially open prior to be closed by one or more nonvolatile specific commands to a write overlay window to close the overlay window(s) and enable direct write operations to an underlying physical nonvolatile memory if that capability is available.

Because a write overlay window does not have to be explicitly opened prior to a write operation, there may therefore be no requirement that a protocol-specific command be created to open such an overlay window. In order to subsequently open a read overlay window, for example, certain information may be written to a write overlay window. For example, information may be written to a particular register of a write overlay window and writing to such a register may cause an internal controller or processor of a nonvolatile memory device to subsequently perform a process to open a read overlay window.

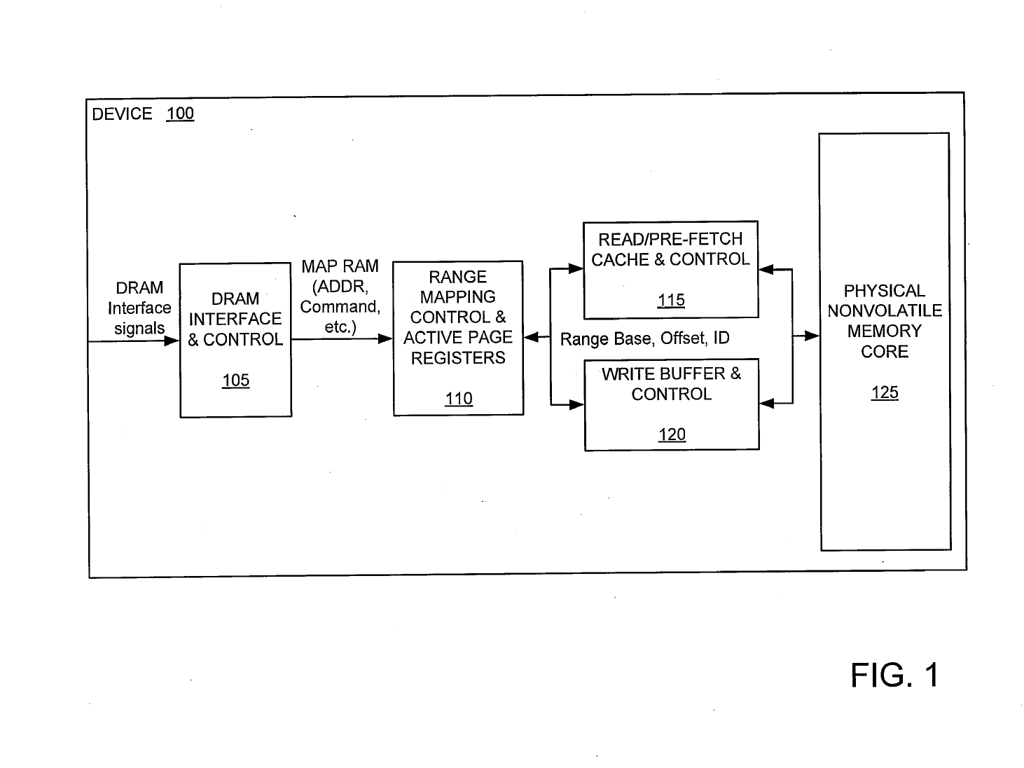

FIG. 1 illustrates a nonvolatile memory device 100 according to one implementation. As shown, nonvolatile memory device 100 may include several elements, such as a DRAM Interface and Control 105, Range Mapping Control and Active Page Registers 110, Read/Pre-fetch Cache and Control 115, Write Buffer and Control 120, and Physical Nonvolatile Memory Core 125. Nonvolatile memory device 100 may comprise, for example, a flash memory, Phase-Change Memory (“PCM”), or Electrically Erasable Programmable Read-Only Memory (“EEPROM”).

DRAM Interface and Control 105 may be adapted to receive DRAM interface signals for a DRAM-compatible bus or device, such as an LPDDR-NVW bus. DRAM Interface and Control 105 may transmit MAP RAM information, such as addresses or commands to Range Mapping Control and Active Page Registers 110. Read/Pre-fetch Cache and Control 115 and Write Buffer and Control 120 may utilize a temporary memory, such as a Static Random Access Memory (SRAM), in which one or more read overlay windows and/or write overlay windows may be presented. Read/Pre-fetch Cache and Control 115 may read commands or data from registers within Physical Nonvolatile Memory Core 125. Write Buffer and Control 120 may write data or commands to registers within Physical Nonvolatile Memory Core 125. Physical Nonvolatile Memory Core 125 may comprise cells to which information, such as data or program code, for example, may be stored.

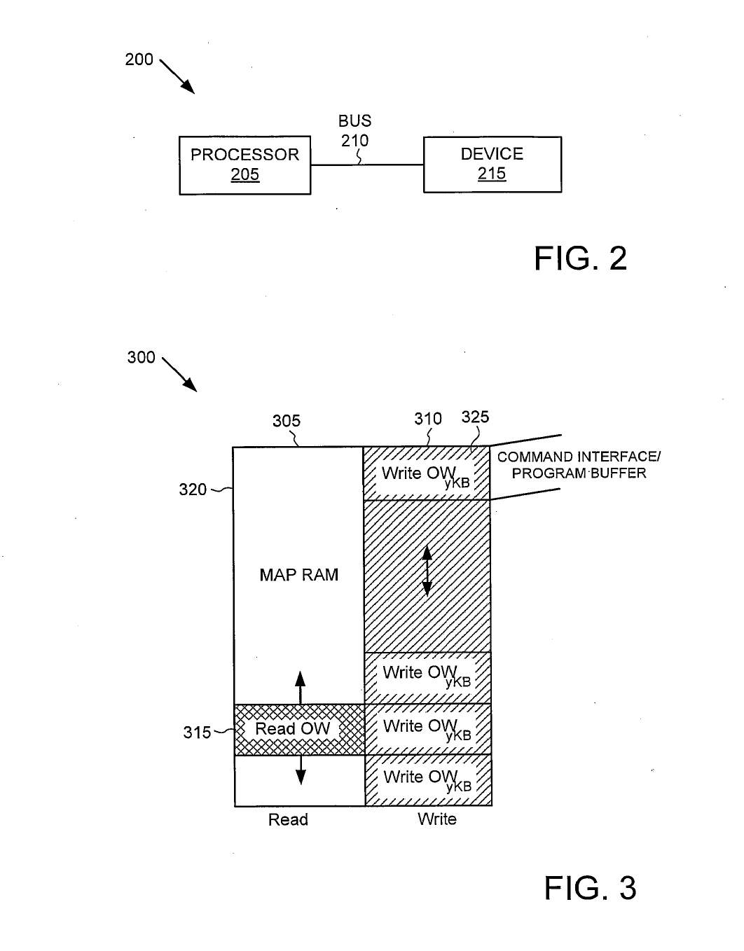

FIG. 2 illustrates an electronic system 200 according to one implementation. Electronic system may include a processor 205, a bus 210, and a nonvolatile memory device 215. Processor 205 may be adapted to generate a read command to read data or other information from nonvolatile memory device 215, and to generate a write command to write data or other information to nonvolatile memory device 215. Processor 205 may transmit a read and/or write command across bus 210 to nonvolatile memory device 215. As discussed herein, nonvolatile memory device 215 may permit a direct read operation, such that information may be read directly from a physical nonvolatile memory by an electronic device external to nonvolatile memory device 215, such as processor 205 in this example. Nonvolatile memory device 215 may also prohibit a direct write operation, whereby information may not be written directly to a physical nonvolatile memory by an electronic device external to nonvolatile memory 215, such as processor 205.

Nonvolatile memory device 215 may include both a physical nonvolatile memory and a temporary memory, such as those discussed above with respect to FIG. 1. When a write command is received, information may be written to a write overlay window within a buffer of a temporary memory, as discussed below with respect to FIG. 3.

FIG. 3 illustrates a memory space 300 for a non-volatile memory device having two separate overlay window types, a read overlay window and write overlay window, according to one implementation. Each overlay window type may be logically separate but may reside in the same memory space according to one implementation. Memory space 300 may include read overlay window registers 305 and write overlay window registers 310. In read overlay window space 305, for example, at least one read overlay window 315 may be present. In this example, read overlay window 315 may include registers for the purpose of conveying command response data, command or device status or any information that would not naturally be via another mechanism. Read overlay window 315 may also include one or more status registers to store status information. Such status information may indicate, for example, information associated with various particulars of a nonvolatile memory, whether certain commands have been executed, how RAM is partitioned, and whether errors have occurred, for example.

In the example shown in FIG. 3, information may be read directly from a read overlay window 315 or from MAP RAM 320. MAP RAM 320 may be adapted to store program code, for example, among other types of information. Information can be read directly from MAP RAM 320 if a read overlay window 315 is not already open. In the event that a read overlay window 315 is open, such a read overlay window 315 may be closed to allow information to be read from MAP RAM 320. On the other hand, if information is to be read from a read overlay window 315, such a read overlay window 315 would need to remain open during execution of a read process.

Write overlay window registers 310 may be accessed via one or more write overlay windows 325. An initial state of device nonvolatile memory device at reset is such that the entire memory space may be tiled with open write overlay windows. It is only by subsequent nonvolatile memory commands to an open write overlay window that select write overlay windows may be closed in order to leave only certain desired overlay window location open. A process, as discussed herein, may be related to initialization of a nonvolatile memory device. Each of the write overlay windows 325 may be utilized to store information received from an external device, such as processor 205 of FIG. 2. There may be multiple write overlay windows. Use of multiple overlay windows after initialization during a boot process may be a choice of a nonvolatile memory device. “Host,” as used herein, may refer to a master device that issues commands or accesses a non-volatile memory's capabilities. A write overlay window 325 may also include a command interface and/or a program buffer.

In one implementation, one or more write overlay windows 325 may remain open because a direct write to underlying physical nonvolatile memory is not permitted. On the other hand, one or more read overlay windows mayor may not be open at a particular time, e.g., in order to allow read access to an underlying physical nonvolatile memory, because a direct read from underlying physical nonvolatile memory is permitted. Multiple read overlay windows may be valuable if there are multiple virtual masters using a non-volatile memory each with their own memory space partitioned. In order to open a read overlay window, a write overlay window command or protocol may need to be issued or followed, which may cause an internal controller or processor in such a nonvolatile memory device to open one or more read overlay windows.

A Low Power Double Data Rate (LPDDR) Execute in Place (XIP) Nonvolatile Memory (NVM) device may share a memory bus with an LPDDR RAM and may be stacked together in select combinations based on vender options. Customer partitioning control of granularity of NVM vs. RAM may save customer system implementation cost by the same logic that XIP saves cost.

A command interface may be used to permanently or transiently partition a virtual RAM overwrite (OW) flexibly and in small granularities. Between a type of virtual RAM OW and an underlying Phase Change Modulation (PCM) technology exist options and complexities need not need impact a host bust interface. An NVM command interface may be used to authenticate access to various virtual RAM, e.g., mapped RAM, (MAP RAM), memory spaces within a secure execution environment.

Assuming that an underlying NVM has characteristics that allow it to approach read/write performance capabilities of RAM, a virtual RAM OW interface may be used to provide a flexible partitioning capability that may allow a PCM NVM device to potentially be used as a replacement for RAM and XIP NVM at the same time preserving both the best aspects of RAM and NVM XIP memory.

Configuration of size, type and location of MAP RAM may require a command issued through a NVM command interface which could be performed in the factory or in the field. A MAP RAM's duration may be permanent or transient depending on the usage model. Security capabilities for a MAP RAM are discussed herein that may be implemented via a same command interface.

RAM and NVM are often purchased separately and may be stacked to achieve a desired partitioning. An implementation as discussed herein may merge two types of memories into one device. If a nonvolatile memory technology, such as PCM, may be used to implement RAM replacement strategies, an ability to freely configure the proportion of each may provide flexibility, cost savings and allow customers to build more easily and inexpensively Execute in Place (XIP) and Store and Download (SND) architectures using a single device. This aspect may be a foundation for a whole new flexible memory approach bridging RAM, XIP NVM, SND NVM and the fundamental Security of the aforementioned architectures. SND may refer to a type of demand paging. In one particular architecture, a host processor may implement virtual memory using a translation lookaside buffer (TLB) to map virtual addresses to a physical address space. Active Range Mapping relates to SND in that the capability provides a level of abstraction between a MAP RAM memory space and a physical nonvolatile memory space. Use of an Active Range Mapping within a host level SND architecture may allow for interesting new capabilities while accounting for the fact that PCM fundamentally will not be as fast as DRAM and therefore requires some level of additional management.

According to one implementation, a system may be utilized to approximate volatile DRAM behavior by implementing a write buffer/read cache mechanism using volatile memory (e.g., SRAM) in a device comprising a nonvolatile memory. In such a device, the write buffer/read cache mechanism would be implemented as a layer between the MAP RAM interface and the physical nonvolatile memory. In one example, data may be written to a MAP RAM and may subsequently be stored in a physical nonvolatile memory. Some NVM memories may have write endurance problems. For example, although DRAM can be written 10̂15 times, some NVM memories can only be written orders of magnitude fewer times. As a result, some system workloads may benefit from the write buffering/read caching layer between the interface and the physical memory. Bypassing accessed data that has been committed to a physical memory but currently resides in a write buffer may be a useful way of cutting down the number of actual writes to physical memory of an NVM. In such bypass situations, a read cache or prefetch buffer may be used to store likely future read accesses that are currently available (e.g., those that do not have to be sensed from an NVM core).

Use of a virtual addressing scheme with a capability to dynamically remap a background physical NVM via a host command may eliminate a need to transfer data from a distant non-volatile storage in an Input/Output (IO) subsystem to a host memory system (DRAM) in demand paging systems, because the described device sits on the DRAM bus and is a essentially a virtual memory portal to a larger underlying non-volatile memory. An implementation may combine Demand Paging and XIP together into a single high performance device.

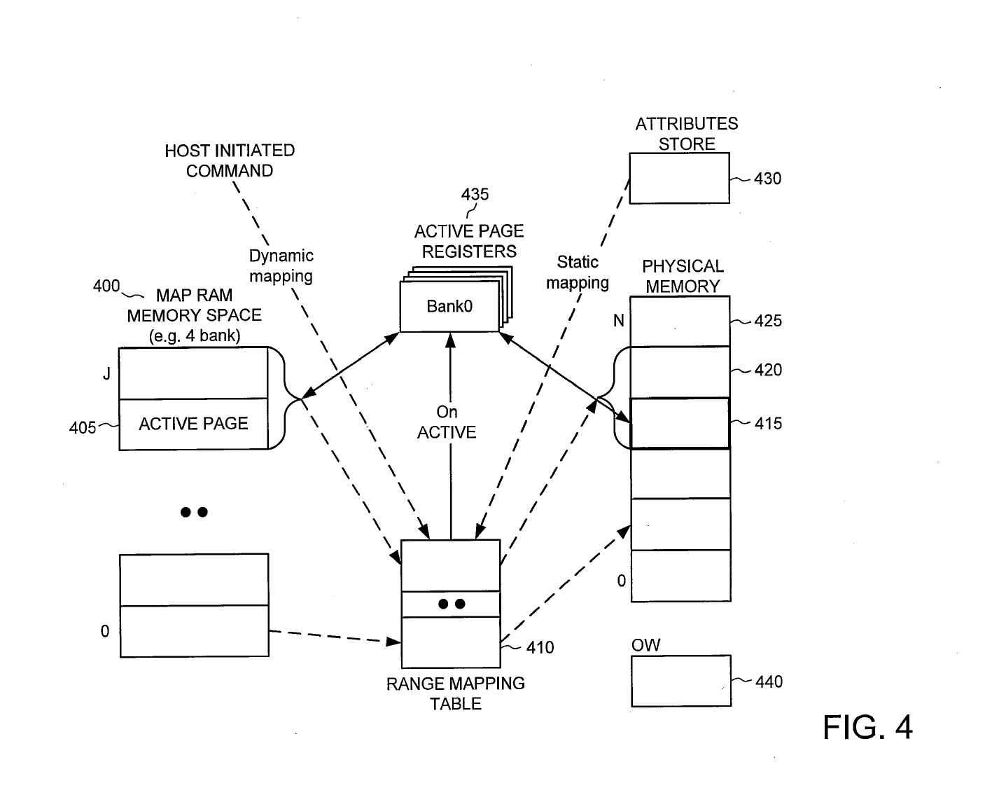

FIG. 4 illustrates an abstraction of elements within a nonvolatile memory according to one implementation. As shown, a MAP RAM memory space 400 includes one or more pages. In this example, a MAP RAM memory space 400 includes j pages. Each page in an MAP RAM memory space 400 may be the same size as a page that may be utilized in DRAM or other type of RAM of the system. By presenting an MAP RAM memory space 400 having pages that are the same size as a page in a DRAM, for example, a nonvolatile memory may function with components that are capable of communicating with such a DRAM, such as an LPDDR bus. In an implementation where a DRAM utilizes a page having 1 KB of memory locations, a page of MAP RAM 400 may also include 1 KB of memory locations, regardless of a page size utilized internally by a nonvolatile memory. In the event that a page of MAP RAM memory space 400 is activated such that its contents may be accessed for a write and/or read operation, a controller within a nonvolatile memory device may refer a range mapping table 410.

Range mapping table 410 may store information mapping a page of MAP RAM 400 with one or more physical page units of physical memory 425. For example, if a page in physical memory 425 holds 64 memory locations, there may be a total of 16 different pages in physical memory 425 that correspond to a particular page in MAP RAM 400. If, on the other hand, a page of physical memory 425 holds 512 memory locations, one page of MAP RAM memory space 400 may instead map to two pages in physical memory 425. In this example, active page 405 may map to pages 415 and 420 of physical memory 425. When page 405 of MAP RAM 400 is activated, range mapping table 410 may be utilized to determine both pages in physical memory 425 corresponding to page 405 and associate attributes for corresponding pages on physical memory 425. Such attributes may indicate whether a page is read-only, write-only, inaccessible, to name just a few examples among many. Such attributes may therefore be used for security purposes to prevent certain memory locations of physical memory 425 from being accessed or written to. Such attributes may be stored in an attributes store 430.

Upon activation of a MAP RAM page the Range mapping table 410 may transmit a message to the associated active page registers 435 indicating specific pages in physical memory 425 to be accessed and attributes for such pages. Such active page registers 435 may be utilized to acquire information/data in pages in physical memory 425 and may write such information/data to a memory page buffer where it may be subsequently processed. For example, such information/data may be transmitted out of a nonvolatile memory device to a processor or other system component for subsequent processing/usage. Active page registers 435 may be associated with one or more banks A “bank” may refer to a partition of a DRAM that essentially operate in an independent fashion. For instance, if there are two banks then each would have independent page buffers or Active Page Registers. In one particular implementation, an overlay window (OW) 440 is utilized by active page registers 435 to access physical memory 425.

Range mapping may have several benefits. For example, it may be utilized to maintain a DRAM or synchronous DRAM (SDRAM) protocol and organization to minimize need to modify a memory controller. Range mapping may also support both XIP & SND for code execution by virtually mapping a larger NVM memory space through a DRAM portal, thereby eliminating a need to physically transfer data. In SND systems, Page Fault handlers may also rely on Range Mapping commands of MAP RAM 400 rather than page swaps (i.e., no physical data transfers over I/O). A Page Fault handler and a File system driver may invoke code to issue MAP RAM (re)mapping commands thereby eliminating the traditional Direct Memory Access (DMA) of page data from IO space to memory space over the associated bus systems.

Another benefit is that range mapping may provide a foundation to build a compile time and/or runtime Quality of Service (QOS) capability allowing mapping of application working sets between MAP RAM & DRAM. This implies direct write access to MAP RAM range mapped pages. Range mapping may support page attributes like Read protection, Write authentication, command or status OW eliminating range registers in critical path. Range mapping may also support future aggregation and/or virtualization strategies.

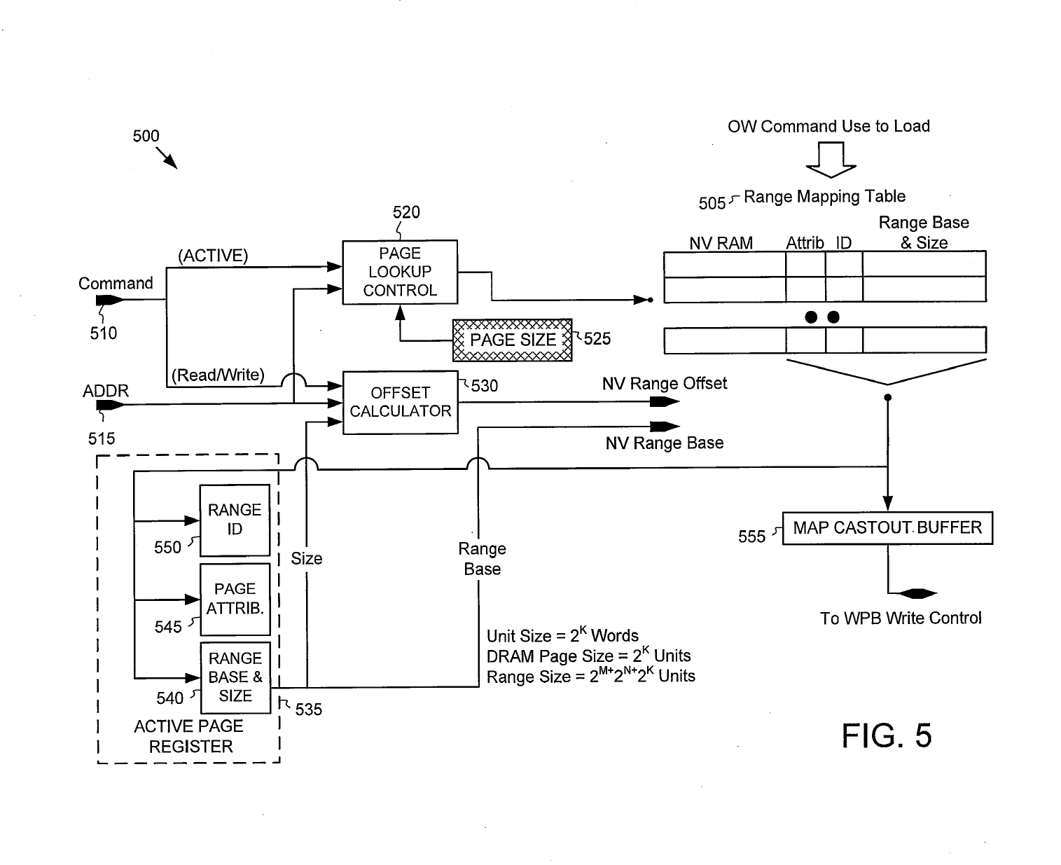

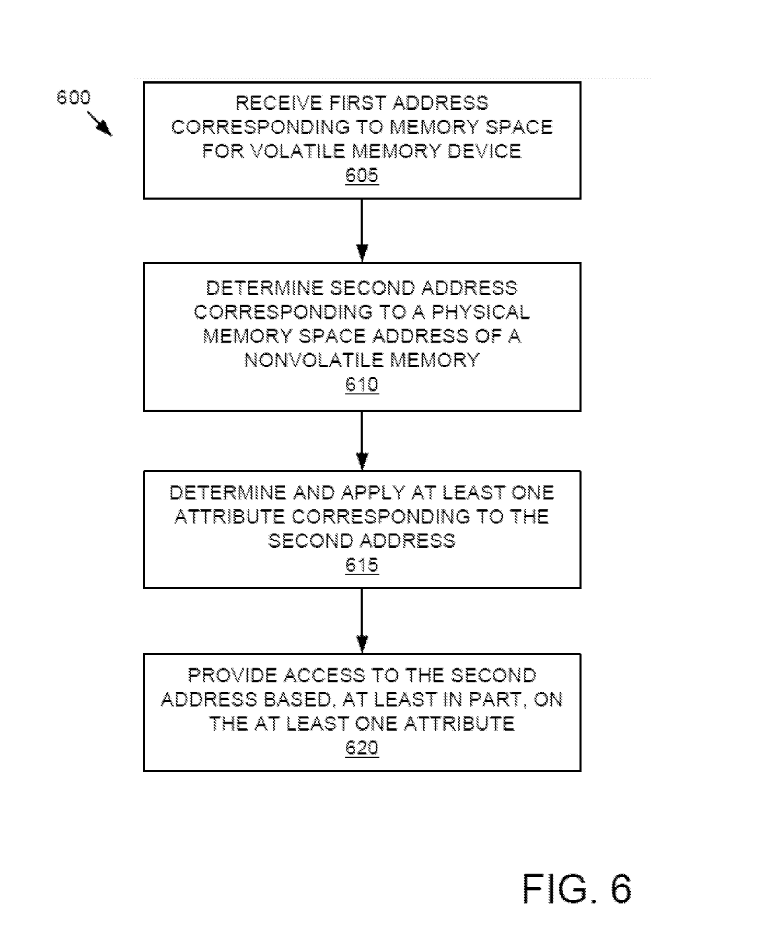

FIG. 5 illustrates a flow chart 500 of a range mapping operation according to an implementation. An overlay window command may be utilized to load a range mapping table entry 505. Likewise, range mapping table entries can be initialized as a result of an internal mechanism triggered by an event such as reset. Range mapping table 505 may include information mapping a MAP RAM memory address to an NV physical memory address, as discussed above with respect to FIG. 4. Range mapping table 505 may include additional information, such as attributes for one or more MAP RAM pages that map to physical nonvolatile memory. Range mapping table may allow for a translation address to be given an ID and be stored in a Content Addressable Memory (CAM). Range mapping table 505 may also include an identifier (ID). Use of such an ID may allow a write buffer/read cache to use the ID rather than the whole address for comparison, thus saving hardware and improving performance.

According to a DRAM interface, such as LPDDR, a command and an address (ADDR) may be received via command input 510 and ADDR input 515, respectively. A command and an address received may be utilized to activate a MAP RAM page range. Such a command and address may be received by a Page Lookup Controller (Cntl) 520, which may access the range mapping table 505 to determine a corresponding entry and thus NVM range of physical memory. Page Lookup Cntl 520 may also receive a page size from a MAP RAM Page Size input 525. In one implementation, a nonvolatile memory device may potentially emulate multiple DRAM device types via a MAP RAM Page Size input 525 and behave as a universal memory device. An address and command may also be provided to a NVM Range Offset Calculator 530, which may require a Range Base and Size, which is a component of the Range Mapping Table entry transferred to the Active Page Register and the MAP RAM Page Size input 525. Upon receiving a DRAM CAS cycle, Range Offset Calculator 525 may need to select appropriate bits to access requested NV physical memory page data. To accomplish this aspect, NVM Range Offset Calculator 530 may generate an NVM Range Offset.

Active Page Register may store an NVM Range Base and Size associated with the entire mapped range which may include many NV physical memory pages. The MAP RAM Page Size is naturally equal to or less than NVM Range Size of the Range Mapping Table entries. However, the MAP RAM Page Size may be equal to or greater than a fundamental NV physical memory page (unit) size. MAP RAM Page Size, NVM Range Base and Size and NV physical memory unit size may need to be aligned. MAP RAM Page Size is configured based on the platform and can be routed to NVM Range Offset Calculator 525. NVM Range Offset Calculator 525 may determine a full NV physical memory address being requested. This may require a register to store upper address bits from a MAP RAM page on a bank basis captured during a RAS if the NVM Range Size is greater than the MAP RAM Page Size and the lower bits during a CAS. The NVM Offset Calculator 525 may, based on the inputs, generate the appropriate NV physical memory address requested.

An active page register 535 may store certain information used when accessing range mapping table 505. For example, active page register 535 may include a NVM Range Base & Size input 540, a NVM Page Attribute input 545, and an NVM Range ID input 550. Page Attribute input 545 may include information indicating attributes for more or more pages in a NV physical memory. NVM Range ID input 550 may include information indicating an ID for one or more pages in NV physical memory.

A Map Castout Buffer 555 may be utilized to store data read from NV physical memory according to one implementation. Map Castout Buffer 555 may hold any entry that was previously in Range Mapping Table that has been replaced or modified where data currently exists in the write buffer. A Range castout must have different ID from anything in the Range Mapping Table even if only an attribute value was changed. Write Buffer contents may be retired to NV physical memory in an orderly fashion so as not to result in incoherency. A write engine may need to access Range Mapping Table and Map Castout Buffer 555 to resolve the physical memory address to write the next write buffer entry. When Map Castout Buffer 555 is full then the device must throttle the host and flush all the Write Buffer entries associated with Range ID before allowing additional writes. It should be appreciated that FIG. 5 illustrates components/elements in one particular implementation and that other implementations may not necessarily utilize the same components.

FIG. 6 illustrates a method 600 for accessing a memory address stored in a nonvolatile memory according to one implementation. First, at operation 605, a first address corresponding to a memory space for a volatile memory device is received. Next, at operation 610, a second address corresponding to a physical memory space address of a nonvolatile memory is determined. At operation 615, at least one attribute corresponding to the second address is determined and applied to the second address. Finally, at operation 620, access to a second address is provided based, at least in part, on the at least one attribute.

A controller may be utilized in a system to implement one or more methods as discussed herein. A controller may include an address translation element to determine, based on a first address corresponding to a memory space for a volatile memory device, a second address corresponding to a physical memory space address of a second memory based on one or more entries stored in a range mapping table. An attribute determination element may determine at least one attribute corresponding to the second address and apply the at least one attribute to the second address. An access element may provide access to the second address based, at least in part, on the at least one attribute.

A second memory may comprise at least one of a Phase-Change Memory (“PCM”), flash memory, and/or Electrically Erasable Programmable Read-Only Memory (“EEPROM”). The at least one attribute may comprise at least one of a quality of service (QOS), read or write access, a requirement to gain read or write access, a security method, or a method by which to gain read or write access including one or more security authentication methods.

Such a controller may be adapted to inhibit access to the second address based, at least in part, on the least one attribute. Such a controller may be adapted to map the first address to the second address in a factory or modifying the mapping during operation of the second memory. Such a controller may be adapted to require use of one or more security methods to performing the mapping of the first address to the second address.

Some exemplary methods and systems are described herein that may be used to allow a nonvolatile memory device to be utilized with RAM interface, such as DRAM. A nonvolatile memory may generate a MAP RAM or virtual RAM abstraction that may be visible to devices external to the nonvolatile memory. Such a nonvolatile memory may receive read and/or write requests and refer to an active ranging table to determine a corresponding address location in a physical nonvolatile memory. Security may be applied by storing attributes for particular pages in physical nonvolatile memory which may indicate whether a read and/or write operation is allowed to a particular page.

While certain exemplary techniques have been described and shown herein using various methods and systems, it should be understood by those skilled in the art that various other modifications may be made, and equivalents may be substituted, without departing from claimed subject matter. Additionally, many modifications may be made to adapt a particular situation to the teachings of claimed subject matter without departing from the central concept described herein. Therefore, it is intended that claimed subject matter not be limited to the particular examples disclosed, but that such claimed subject matter may also include all implementations falling within the scope of the appended claims, and equivalents thereof.

1. (canceled)

2. An apparatus comprising:
a non-volatile memory having a plurality of physical pages; and
an interface configured to communicate with a bus according to a dynamic random access memory (DRAM) protocol such that data is transferred in units of DRAM pages, wherein the interface is configured to communicate with the non-volatile memory, wherein the interface is configured to provide an overlay window to map a range of physical pages of the non-volatile memory to an address space corresponding to one or more DRAM pages.

3. The apparatus of claim 2, wherein the interface is configured to provide a default overlay window.

4. The apparatus of claim 2, wherein the overlay window is configurable during runtime to remap associations between the physical pages and the address spaces of the one or more DRAM pages.

5. The apparatus of claim 2, wherein the interface is configured to map the range to the one or more DRAM pages with a range mapping table.

6. The apparatus of claim 5, further comprising a content addressable memory (CAM) configured to store one or more translation addresses in the range mapping table.

7. The apparatus of claim 5, further comprising a content addressable memory (CAM) configured to store one or more identifiers for one or more translation addresses in the range mapping table.

8. The apparatus of claim 5, wherein the non-volatile memory comprises at least one of a Phase-Change Memory (“PCM”), a flash memory, or an Electrically Erasable Programmable Read-Only Memory (“EEPROM”).

9. A method of mapping memory, the method comprising:
communicating with a bus according to a dynamic random access memory (DRAM) protocol such that data is transferred in units of DRAM pages;
communicating with a non-volatile memory; and
providing an overlay window to map a range of physical pages of the non-volatile memory to an address space corresponding to one or more DRAM pages.

10. The method of claim 9, wherein the overlay window comprises a default overlay window.

11. The method of claim 9, further comprising configuring the overlay window during runtime to remap associations between the physical pages and the address spaces of the one or more DRAM pages.

12. The method of claim 9, further comprising mapping the range to the one or more DRAM pages with a range mapping table.

13. The method of claim 12, further comprising storing one or more translation addresses in a content addressable memory (CAM) for the range mapping table.

14. The method of claim 12, further comprising storing one or more identifiers for one or more translation addresses in a content addressable memory (CAM) for the range mapping table.

15. The method of claim 12, wherein the non-volatile memory comprises at least one of a Phase-Change Memory (“PCM”), a flash memory, or an Electrically Erasable Programmable Read-Only Memory (“EEPROM”).

16. A controller comprising:
an interface configured to communicate with a bus according to a dynamic random access memory (DRAM) protocol such that data is transferred in units of DRAM pages, wherein the interface is configured to communicate with a non-volatile memory, wherein the interface is configured to provide an overlay window to map a range of physical pages of the non-volatile memory to an address space corresponding to one or more DRAM pages; and
a range mapping table configured to store one or more translation addresses or identifiers for translation addresses.

17. The controller of claim 16, wherein the interface is configured to provide a default overlay window.

18. The controller of claim 16, wherein the overlay window is configurable during runtime to remap associations between the physical pages and the one or more DRAM page address spaces.

19. The controller of claim 16, further comprising a content addressable memory (CAM) configured to store one or more translation addresses in the range mapping table.

20. The controller of claim 16, further comprising a content addressable memory (CAM) configured to store one or more identifiers for one or more translation addresses in the range mapping table.

21. The controller of claim 16, wherein the non-volatile memory comprises at least one of a Phase-Change Memory (“PCM”), a flash memory, or an Electrically Erasable Programmable Read-Only Memory (“EEPROM”).
